(19) United States
(12) Patent Application Publication
(10) Pub. No.: US 2025/0079159 A1
(43) Pub. Date: Mar. 6, 2025

(54) METHOD FOR IMPROVED SILICON DEPOSITION

(71) Applicant: ASM IP Holding, B.V., Almere (NL)

(72) Inventors: Dieter Pierreux, Pepingen (BE); Steven Van Aerde, Tielt-Winge (BE); Kelly Houben, Lubbeek (BE); Bert Jongbloed, Oud-Heverlee (BE)

(21) Appl. No.: 18/815,701

(22) Filed: Aug. 26, 2024

Related U.S. Application Data
(60) Provisional application No. 63/535,260, filed on Aug. 29, 2023.

(51) Int. Cl. H01L 21/02; C23C 16/40; C23C 16/455

(52) U.S. Cl. CPC H01L 21/0228; C23C 16/401; C23C 16/45553; H01L 21/02164; H01L 21/02211

(57) ABSTRACT

The technology of the present disclosure generally relates to the field of semiconductor devices. More particularly, semiconductor structures, systems, and methods for producing the same, comprising surface-modified silicon layers formed by reacting a deposited silicon layer with a halide reactant. The system comprising one or more reaction chamber constructed and arranged to hold a substrate; a silicon precursor vessel constructed and arranged to contain and evaporate a silicon precursor; a halide reactant vessel constructed and arranged to contain and evaporate a halide reactant; an exhaust source; and a controller; wherein the controller is configured to control the flow of said silicon precursor and said halide reactant into said reaction chamber, thereby forming a surface-modified silicon layer on said substrate.

### CROSS-REFERENCE TO RELATED APPLICATION(S)

This application claims the benefit of U.S. Provisional Application 63/535,260 filed on Aug. 29, 2023, the entire contents of which are incorporated herein by reference.

### FIELD OF INVENTION

The present disclosure generally relates to the field of semiconductor devices, manufacturing processes and systems. More particularly, systems and methods suitable for forming semiconductor structures comprising surface-modified silicon layers are disclosed.

### BACKGROUND OF THE DISCLOSURE

To increase functionality, while shrinking device dimensions, the modern semiconductor industry is facing several processing challenges. Semiconductor manufacturing involves a series of complex processes such as deposition, etching, lithography, and doping. Even minor variations in these processes can result in non-uniform material properties or device characteristics across the wafer. Process variation can be caused by factors like equipment calibration, temperature fluctuations, or chemical composition inconsistencies. For instance, when thin silicon films are deposited onto the wafer to form various device layers, non-uniform deposition rates or film thickness can lead to variations in electrical properties, structural integrity, and semiconductor performance. One particular problem is the so-called “edge effect”, which occurs when excess silicon material is deposited towards the edge of the surface of a wafer. In traditional semiconductor manufacturing, the excess silicon is typically polished or etched after deposition to smoothen the surface and achieve a certain layer thickness and surface roughness. Nonetheless, non-uniform or non-selective etching may lead to uneven feature depths, which may affect the electronic properties of the semiconductor device. Therefore, there is a need to remedy the aforementioned constraints of present semiconductor manufacturing technology by providing a method for improved silicon deposition with increased uniformity and high yield.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure relates to a system comprising:
one or more reaction chamber constructed and arranged to hold a substrate;
a silicon precursor vessel constructed and arranged to contain and evaporate a silicon precursor;
a halide reactant vessel constructed and arranged to contain and evaporate a halide reactant;
an exhaust source; and
a controller;
wherein the controller is configured to control the flow of said silicon precursor and said halide reactant into said reaction chamber, thereby forming a surface-modified silicon layer on said substrate.

In a particular embodiment, the system as disclosed herein provides that the system further comprises an oxygen reactant vessel constructed and arranged to contain and evaporate an oxygen reactant; and wherein the controller is configured to control the flow of said oxygen reactant into said reaction chamber, thereby forming a surface-modified silicon oxide layer on said substrate.

In a particular embodiment, the system as disclosed herein provides that the system further comprises a nitrogen reactant vessel constructed and arranged to contain and evaporate a nitrogen reactant; and wherein the controller is configured to control the flow of said nitrogen reactant into said reaction chamber, thereby forming a surface-modified silicon nitride layer on said substrate.

In another aspect, the present disclosure provides a method for precursor deposition in a semiconductor manufacturing process, the method comprising the steps of:
a) providing a substrate to a reaction chamber;
b) executing one or more cycles, a cycle comprising
   i. contacting a silicon precursor with at least a part of said substrate by introducing said silicon precursor in the reaction chamber;
   ii. contacting a halide reactant with at least a part of said substrate by introducing said halide reactant in said reaction chamber, thereby forming a surface-modified silicon layer on at least part of the substrate.

In a particular embodiment, the method as disclosed herein provides that the cycle of step b) further comprises contacting an oxygen reactant with at least a part of said substrate by introducing said oxygen reactant in said reaction chamber; thereby forming a surface-modified silicon oxide layer on at least part of said substrate.

In a particular embodiment, the method as disclosed herein provides that the cycle of step b) further comprises contacting a nitrogen reactant with at least a part of said substrate by introducing said nitrogen reactant in said reaction chamber; thereby forming a surface-modified silicon nitride layer on at least part of said substrate.

In a particular embodiment, the method as disclosed herein provides that said silicon precursor and said halide reactant are simultaneously introduced in said reaction chamber.

In a particular embodiment, the method as disclosed herein provides that said silicon precursor is introduced in said reaction chamber prior to said halide reactant.

In a particular embodiment, the method as disclosed herein provides that said silicon precursor and said halide reactant are introduced in said reaction chamber at a volumetric flow rate ratio of silicon precursor/halide reactant of at least 1.1 to at most 100.0.

In a particular embodiment, the method as disclosed herein provides that said silicon precursor is chosen from the group including at least one of SiₙH₂ₙ₊₂, SiₙH₂ₙ, and Si(OR¹)₄; wherein n is an integer from 1 to 20 and m is an integer from 3 to 20; and wherein each R¹ is independently selected from the group consisting of C₁₋₈alkyl.

In a particular embodiment, the method as disclosed herein provides that the silicon precursor is chosen from the group consisting of silane (SiH₄), disilane (Si₂H₆), trisilane (Si₃H₈), tetrasilane (Si₄H₁₀), isotetrasilane, pentasilane (Si₅H₁₂), isopentasilane, neopentasilane, hexasilane (Si₆H₁₄), cyclotrisilane (Si₃H₆), cyclotetrasilane (Si₄H₈), cyclopentasilane (Si₅H₁₀), cyclohexasilane (Si₆H₁₂), tetramethyl orthosilicate (Si(OCH₃)₄), and tetraethyl orthosilicate (Si(OC₂H₅)₄).

In a particular embodiment, the method as disclosed herein provides that said halide reactant is selected from the group consisting of elemental halogen, and a halogen compound; and wherein the halogen compound comprises an element selected from the group consisting of H, B, Al, Si, P, O, N, and S, and one or more halogen.

In a particular embodiment, the method as disclosed herein provides that said halide reactant may be chosen from the group consisting of fluorine (F₂), chlorine (Cl₂), bromine (Br₂), iodine (I₂), hydrogen fluoride (HF), hydrogen chloride (HCl), hydrogen bromide (HBr), hydrogen iodide (HI), phosphorus trifluoride (PF₃), phosphorus pentafluoride (PF₅), phosphorus trichloride (PCl₃), phosphorus pentachloride (PCl₅), thionyl chloride (SOCl₂), phosphorus tribromide (PBr₃), phosphorus pentabromide (PBr₅), thionyl bromide (SOBr₂), tetrafluorosilane (SiF₄), tetrachlorosilane (SiCl₄), tetrabromosilane (SiBr₄), trifluorosilane (SiHF₃), trichlorosilane (SiHCl₃), tribromosilane (SiHBr₃), difluorosilane (SiH₂F₂) dichlorosilane (SiH₂Cl₂), dibromosilane (SiH₂Br₂), fluorosilane (SiH₃F), chlorosilane (SiH₃Cl), bromosilane (SiH₃Br), hexafluorodisilane (Si₂F₆), hexachlorodisilane (Si₂Cl₆), hexabromodisilane (Si₂Br₆), octafluorotrisilane (Si₃F₈), octachlorotrisilane (Si₃Cl₈), octabromotrisilane (Si₃Br₈), boron trifluoride (BF₃), boron trichloride (BCl₃), boron tribromide (BBr₃), boron triiodide (BI₃), aluminium trifluoride (AlF₃), aluminium trichloride (AlCl₃), aluminium tribromide (AlBr₃), and aluminium triiodide (AlI₃).

In a particular embodiment, the method as disclosed herein provides that the substrate may be made from silicon oxide, silicon germanium, gallium arsenide, indium gallium arsenide, gallium nitride, and/or silicon nitride.

In a particular embodiment, the method as disclosed herein provides that the formed surface-modified silicon layer has an average growth rate of at least 0.05 nm/min.

In a particular embodiment, the method as disclosed herein provides that the formed surface-modified silicon layer has an average growth rate of at least 0.10 nm/min.

In a particular embodiment, the method as disclosed herein provides that the substrate may be heated to a temperature of at least 200° C. and at most 1000° C., preferably at least 350° C. and at most 650° C.

In a particular embodiment, the method as disclosed herein provides that the reaction chamber has a pressure of at least 0.1 Torr and at most 50.0 Torr, preferably at least 0.5 Torr and at most 10 Torr.

In a particular embodiment, the method as disclosed herein provides that the surface-modified silicon layer has an average surface roughness deviation of less than 10.0%.

In a particular embodiment, the method as disclosed herein provides that the surface-modified silicon layer has an average surface roughness deviation of less than 3.0%.

In a particular embodiment, the method as disclosed herein provides that the surface-modified silicon layer has an average thickness of 1 nm or less.

In a particular embodiment, the method as disclosed herein provides that the steps of depositing the silicon precursor and reacting the deposited silicon layer with the halide reactant are repeated two or more times to obtain a target average thickness.

In a particular embodiment, further comprising a step c) of doping the formed surface-modified silicon layer with a dopant, wherein the dopant comprises an element from the group including at least one of P, As, Sb, B, Al, and In.

In a particular embodiment, the method as disclosed herein further provides that the dopant may be chosen from the group consisting of PH₃, PF₅, PCl₅, PBr₅, AsF₅, AsCl₅, AsBr₅, AsH₃, SbF₃, SbCl₃, SbBr₃, BF₃, BCl₃, BBr₃, B₂H₆, AlF₃, AlCl₃, AlBr₃, InF₃, InCl₃, and InBr₃.

Another aspect of the present disclosure relates to a layered structure comprising:
a substrate, and
one or more surface-modified silicon layers deposited on at least part of the substrate;
characterized in that the one or more surface-modified silicon layers have an average surface roughness deviation of less than 10.0%.

In a particular embodiment, the layered structure as disclosed herein provides that the one or more surface-modified silicon layers have an average surface roughness deviation of less than 3.0%.

In a particular embodiment, the layered structure as disclosed herein provides that the one or more surface-modified silicon layers are obtained according to the method as disclosed herein.

In a particular embodiment, the layered structure as disclosed herein provides that each of the one or more surface-modified silicon layers has an average thickness of 1 nm or less.

In a particular embodiment, the layered structure further comprises a dopant, and wherein the dopant comprises an element from the group including at least one of P, As, Sb, B, Al, and In.

Another aspect of the present disclosure relates to the use of a halide reactant for reducing the With-In Wafer Non-Uniformity (WIWNU) of surface-modified silicon layers.

In a particular embodiment, the use as disclosed herein provides that said surface-modified silicon layers have an average surface roughness deviation of less than 10.0%.

In a particular embodiment, the use as disclosed herein provides that said surface-modified silicon layers have an average surface roughness deviation of less than 3.0%.

In a particular embodiment, the use as disclosed herein provides that halide reactant may be chosen from fluorine (F₂), chlorine (Cl₂), bromine (Br₂), iodine (I₂), hydrogen fluoride (HF), hydrogen chloride (HCl), hydrogen bromide (HBr), hydrogen iodide (HI), phosphorus trifluoride (PF₃), phosphorus pentafluoride (PF₅), phosphorus trichloride (PCl₃), phosphorus pentachloride (PCl₅), thionyl chloride (SOCl₂), phosphorus tribromide (PBr₃), phosphorus pentabromide (PBr₅), thionyl bromide (SOBr₂), tetrafluorosilane (SiF₄), tetrachlorosilane (SiCl₄), tetrabromosilane (SiBr₄), trifluorosilane (SiHF₃), trichlorosilane (SiHCl₃), tribromosilane (SiHBr₃), difluorosilane (SiH₂F₂) dichlorosilane (SiH₂Cl₂), dibromosilane (SiH₂Br₂), fluorosilane (SiH₃F), chlorosilane (SiH₃Cl), bromosilane (SiH₃Br), hexafluorodisilane (Si₂F₆), hexachlorodisilane (Si₂Cl₆), hexabromodisilane (Si₂Br₆), octafluorotrisilane (Si₃F₈), octachlorotrisilane (Si₃Cl₈), octabromotrisilane (Si₃Br₈), boron trifluoride (BF₃), boron trichloride (BCl₃), and/or boron tribromide (BBr₃), boron triiodide (BI₃), aluminium trifluoride (AlF₃), aluminium trichloride (AlCl₃), aluminium tribromide (AlBr₃), aluminium triiodide (AlI₃).

### DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 describes an exemplary embodiment of a method for precursor deposition in a semiconductor manufacturing process of the present disclosure. The method starts (111) after a substrate has been provided to a reaction chamber. The cyclical deposition process comprises contacting a silicon precursor with at least a part of the surface of the substrate in a silicon precursor pulse (112). Optionally, the reaction chamber is purged (113) after the silicon precursor pulse (112). Then, a halide reactant compound is provided to the reaction chamber in a halide reactant pulse (114). Optionally, the reaction chamber can be purged (115) after the halide reactant pulse. The silicon precursor pulse (112), the halide reactant pulse (114), and the optional purges (113,115) can be repeated (116) any number of times to obtain a surface-modified silicon layer or film having a desired thickness. When a surface-modified silicon layer having a desired thickness has been deposited, the method ends (117). Once the method has ended, the substrate can, for example, be subjected to additional processes to form a device structure and/or device.

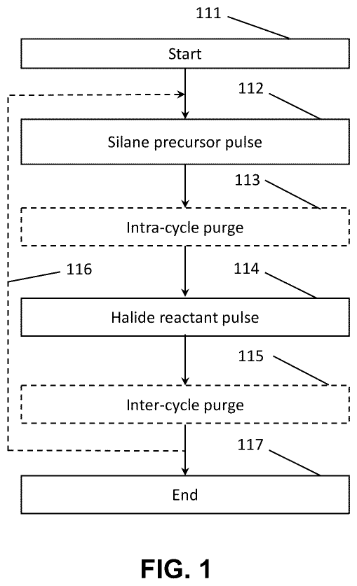

FIG. 2 describes an exemplary embodiment of a method for precursor deposition in a semiconductor manufacturing process of the present disclosure. The method starts (211) after a substrate has been provided to a reaction chamber. The cyclical deposition process comprises providing a halide reactant to the reaction chamber in a halide reactant pulse (212). Optionally, the reaction chamber is purged (213) after the halide reactant pulse (212). Then, a silicon precursor is contacted with at least a part of the substrate in a silicon precursor pulse (214). Optionally, the reaction chamber can be purged (215) after the silicon precursor pulse. The halide reactant pulse (212), the silicon precursor pulse (214), and the optional purges (213,215) can be repeated (216) any number of times to obtain a surface-modified silicon layer having a desired thickness. When a surface-modified silicon layer having a desired thickness has been deposited, the method ends (217). Once the method has ended, the substrate can, for example, be subjected to additional processes to form a device structure and/or device.

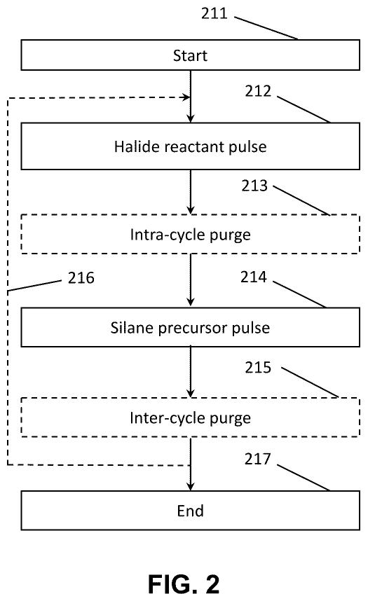

FIG. 3 describes an exemplary embodiment of a method for precursor deposition in a semiconductor manufacturing process of the present disclosure. The method starts (311) after a substrate has been provided to a reaction chamber. The cyclical deposition process comprises contacting a silane precursor with at least a part of the surface of the substrate and reacting the deposited silicon layer with a halide reactant in a combined silicon precursor and halide reactant pulse (312). Optionally, the reaction chamber is purged (313) after the combined silicon precursor and halide reactant pulse (312). The combined silicon precursor and halide reactant pulse (312), and the optional purges (313) can be repeated (314) any number of times to obtain a surface-modified silicon layer or film having a desired thickness. When a surface-modified silicon layer having a desired thickness has been deposited, the method ends (315). Once the method has ended, the substrate can, for example, be subjected to additional processes to form a device structure and/or device.

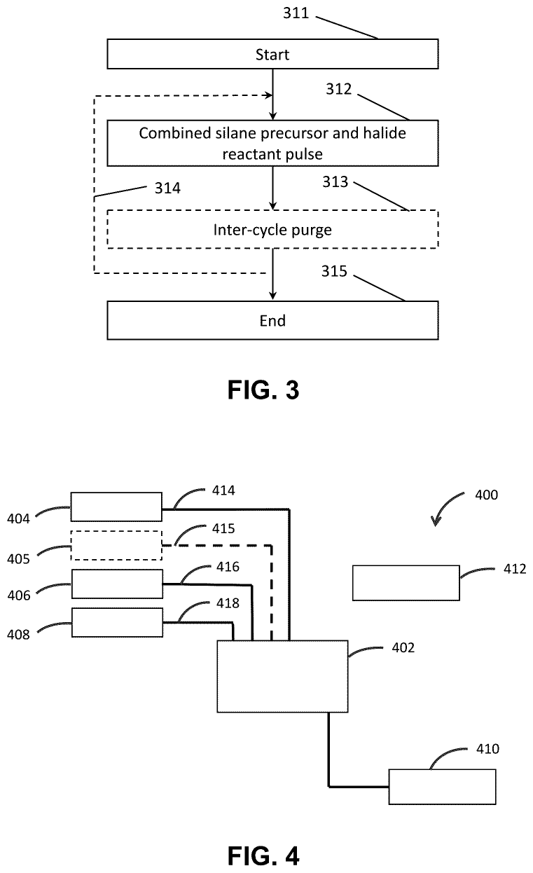

FIG. 4 illustrates a system (400) in accordance with yet additional exemplary embodiments of the disclosure. The system (400) can be used to perform a method as described herein and/or form a structure or device portion as described herein.

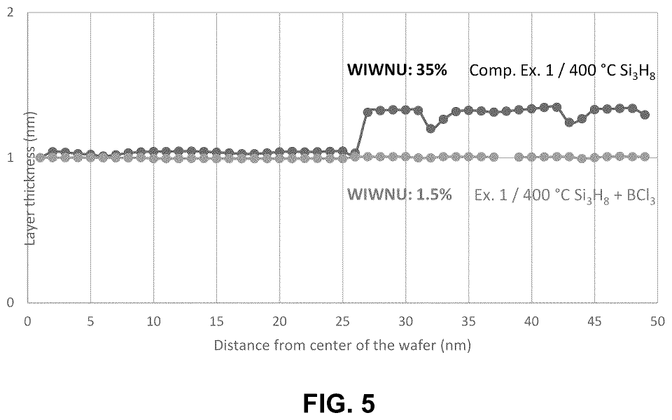

In the illustrated example, the system (400) includes one or more reaction chambers (402), a silicon precursor vessel (404), a halide reactant vessel (406), a purge gas source (408), an exhaust (410), and a controller (412). The reaction chamber (402) can include any suitable reaction chamber, such as an ALD or CVD reaction chamber. Optionally, the system (400) comprises further reactant vessels such as an oxygen reactant and/or nitrogen reactant vessel (405).

The silicon precursor vessel (404) can include a vessel and one or more silicon precursors as described herein-alone or mixed with one or more carrier (e.g., inert) gases. The halide reactant vessel (406) can include a vessel and a halide reactant as described herein-alone or mixed with one or more carrier gases. The purge gas source (408) can include one or more inert gases such as N₂ or a noble gas, as described herein. The system (400) can include any suitable number of gas sources. The gas sources (404)-(408) can be coupled to reaction chamber (402) via lines (414)-(418), which can each include flow controllers, valves, heaters, and the like. The exhaust (410) can include one or more vacuum pumps.

The controller (412) includes electronic circuitry and software to selectively operate valves, manifolds, heaters, pumps and other components included in the system (400). Such circuitry and components operate to introduce precursors, reactants, and purge gases from the respective sources (404)-(408). The controller (412) can control timing of gas pulse sequences, temperature of the substrate and/or reaction chamber, pressure within the reaction chamber, and various other operations to provide proper operation of the system (400). The controller (412) can include control software to electrically or pneumatically control valves to control flow of precursors, reactants and purge gases into and out of the reaction chamber (402). The controller (412) can include modules such as a software or hardware component, e.g., a FPGA or ASIC, which performs certain tasks. A module can advantageously be configured to reside on the addressable storage medium of the control system and be configured to execute one or more processes.

Other configurations of the system (400) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (402). Further, as a schematic representation of a system, many components have been omitted for simplicity of illustration, and such components may include, for example, various valves, manifolds, purifiers, heaters, containers, vents, and/or bypasses.

During operation of the reactor system (400), substrates, such as semiconductor wafers (not illustrated), are transferred from, e.g., a substrate handling system to reaction chamber (402). Once substrate(s) are transferred to the reaction chamber (402), one or more gases from the gas sources (404)-(408), such as precursors, reactants, carrier gases, and/or purge gases, are introduced into reaction chamber (402).

FIG. 5 shows a graphic representation of the deviation in layer thickness of the deposited silicon layer without the addition of a halide reactant (Comparative Example 1) and with the addition of a halide reactant (Example 1).

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” said recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₈alkyl”, as a group or part of a group, refers to a hydrocarbyl group of formula-CₙH₂ₙ₊₁ wherein n is a number ranging from 1 to 8. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

The term “halo” or “halogen” as a group or part of a group may be generic for fluoro (F), chloro (Cl), bromo (Br), iodo (I).

In this disclosure, “gas” can include material that may be a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In general, the technology disclosed herein relates to the field of semiconductor devices, and more specifically to a system for semiconductor manufacturing used in the production of several electronic components such as microprocessors, integrated circuit chips, and memory chips. An important step of the semiconductor formation referred to herein is the reaction between a deposited silicon compound (e.g. silicon, silicon oxide and/or silicon nitride) and/or any intermediate and a halide reactant, such as elemental halogens and/or other halogenating agents, compounds, or reagents. Advantageously, it has been found that the herein disclosed system allows to control the epitaxial growth rate (i.e. crystal growth rate) of silicon monolayers to reduce With-In Wafer Non-Uniformity (WIWNU), resulting in uniform layers with controlled thickness and surface roughness. In general, the system disclosed herein comprises a reaction chamber, a plurality of vessels or gas sources, and a controller to control the flow from said plurality of vessels or gas sources to said reaction chamber. The controlled co-flow or sequential flow of precursors and reactants from said plurality of vessels or gas sources to said reaction chamber of the herein disclosed system allows to regulate the precise ratio of each component even for materials with complex stoichiometries. Moreover, in contrast with state of the art deposition systems and methods, the present disclosure allows for area-selective deposition without the need for additional etchants or specific covering tools.

As set forth in more detail below, various embodiments of the present disclosure relate to a system comprising:
one or more reaction chamber constructed and arranged to hold a substrate;
a silicon precursor vessel constructed and arranged to contain and evaporate a silicon precursor;
a halide reactant vessel constructed and arranged to contain and evaporate a halide reactant;
an exhaust source; and
a controller;
wherein the controller is configured to control the flow of said silicon precursor and said halide reactant into said reaction chamber, thereby forming a surface-modified silicon layer on said substrate.

In a particular embodiment, the system as disclosed herein provides that the system further comprises an oxygen reactant vessel constructed and arranged to contain and evaporate an oxygen reactant; and wherein the controller is configured to control the flow of said oxygen reactant into said reaction chamber, thereby forming a surface-modified silicon oxide layer on said substrate.

In a particular embodiment, the system as disclosed herein provides that the system further comprises a nitrogen reactant vessel constructed and arranged to contain and evaporate a nitrogen reactant; and wherein the controller is configured to control the flow of said nitrogen reactant into said reaction chamber, thereby forming a surface-modified silicon nitride layer on said substrate.

Another aspect of the present disclosure relates to a method for precursor deposition in a semiconductor manufacturing process, the method comprising the steps of:
a) providing a substrate to a reaction chamber;
b) executing one or more cycles, a cycle comprising
   i. contacting a silicon precursor with at least a part of said substrate by introducing said silicon precursor in the reaction chamber;
   ii. contacting a halide reactant with at least a part of said substrate by introducing said halide reactant in said reaction chamber.
thereby forming a surface-modified silicon layer on at least part of said substrate.

Advantageously, the current inventors have found that the herein disclosed method allows to control the epitaxial growth rate (i.e. crystal growth rate) of silicon monolayers to reduce With-In Wafer Non-Uniformity (WIWNU), resulting in uniform layers with controlled thickness and surface roughness. Without wishing to be bound by theory, the current inventors have found that the observed edge effect is substantially controlled by the formation of polysilicon hydride intermediates during deposition or conversion of silane precursors to silicon layers. Formation of said labile polysilicon hydride intermediates may create differences in silicon growth rate across the surface of the substrate, resulting in non-uniform monolayers. In contrast to the state of the art, the current invention allows to control the silicon growth rate across the surface of the substrate during material deposition without the need for additional polishing or etching.

As used herein, the terms “semiconductor structure” or “semiconductor device” refer to an electronic component that relies on the electronic properties of a semiconductor material for its function. The electrical conductivity of a semiconductor falls between that of a conductor (e.g. copper) and an insulator (e.g. soda-lime silica glass). The herein disclosed method can be used to, for example, form complementary metal-oxide-semiconductor (CMOS) devices, or portions of such devices. However, unless noted otherwise, the disclosure is not necessarily limited to such examples.

In particular, the formation of a film comprising silicon, e.g. a surface-modified silicon film, or layer on a substrate as described herein relates to a cyclical deposition process, such as an atomic layer deposition process or a cyclical chemical vapor deposition process. In some embodiments, the cyclical deposition process comprises one or more cycles. In particular embodiments, the method as disclosed herein comprises at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles. It should be understood that different silicon precursors and/or halide reactants may be used during each cycle.

It should be further understood that other reactants may be introduced during the deposition of the silicon precursor to obtain different silicon-containing layers. In particular embodiments, the method as disclosed herein provides that the cycle of step b) further comprises contacting an oxygen reactant with at least a part of said substrate by introducing said oxygen reactant in said reaction chamber; thereby forming a surface-modified silicon oxide (SiO₂) layer on at least part of said substrate. Suitable oxygen reactants include H₂O, H₂O₂, O₃, O₂, O-containing plasma, N₂O, NO, N₂O₅, and oxygen radicals.

In particular embodiments, the method as disclosed herein provides that the cycle of step b) further comprises contacting a nitrogen reactant with at least a part of said substrate by introducing said nitrogen reactant in said reaction chamber; thereby forming a surface-modified silicon nitride (SiN) layer on at least part of said substrate. Suitable nitrogen reactants include NH₃, diazene (N₂H₂), hydrazine (N₂H₄), methylhydrazine (N₂MeH₃), ethylhydrazine (N₂EtH₃), propylhydrazine (N₂nPrH₃), butylhydrazine (N₂nBuH₃), tert-butylhydrazine (N₂tBuH₃), 1,1-dimethylhydrazine (N₂Me₂H₂), 1,1-diethylhydrazine (N₂Et₂H₂), 1,1-dipropylhydrazine (N₂nPr₂H₂), 1,1-dibutylhydrazine (N₂nBu₂H₂), trimethylsilylhydrazine (N₂[Si(Me)₃]H₂), and tris(trimethylsilyl)silylhydrazine (N₂[Si(Si(Me)₃)₃]H₂). Therefore, the herein disclosed method is not limited to silicon deposition, but can be used to deposit other silicon-containing materials with high area-selective precision, a low surface roughness, and a low number of surface defects.

In particular embodiments, the method as disclosed herein provides that one cycle comprises one or more silicon precursor pulse and one or more halide reactant pulse. In some preferred embodiments, each pulse may be followed by a purge with an inert gas chosen from at least one of N₂ and a noble gas.

A cycle comprises one or more pulses. In some embodiments, at least one pulse involves a self-limiting surface reaction. In some embodiments, all pulses involve a self-limiting surface reaction. In some embodiments, a cycle comprises a silicon precursor pulse and a halide reactant pulse. In the silicon precursor pulse, the silicon precursor may be provided into the reaction chamber. In the halide reactant pulse, the halide reactant may be provided into the reaction chamber. In some embodiments, a cycle comprises a silicon precursor pulse, an oxygen reactant pulse, and a halide reactant pulse. In the oxygen reactant pulse, the oxygen reactant may be provided into the reaction chamber. In some embodiments, a cycle comprises a silicon precursor pulse, a nitrogen reactant pulse, and a halide reactant pulse. In the nitrogen reactant pulse, the nitrogen reactant may be provided into the reaction chamber. It should be understood that the herein disclosed system is configured to control the aforementioned silicon precursor pulse, halide reactant pulse and optional oxygen reactant pulse and/or nitrogen reactant pulse of the herein disclosed method. Hence, by exposing the surface of a substrate to different chemicals, reactants, or precursors, one at a time, a thin film may be gradually deposited through repeated exposure to (non-overlapping) pulses.

As used herein, the term “silicon layer” may be used to identify such a thin film when depositing a silicon precursor on at least part of the substrate. Subsequently, when reacting the silicon layer with a halide reactant, the thin film may be identified as a “surface-modified silicon layer”. It should be understood that depending on the silicon precursor and possible contaminants of the substrate and/or reaction chamber, the herein disclosed surface-modified silicon layer may comprise silicon (Si) and/or silicon oxide (SiO₂). Preferably, the surface-modified silicon layer may be deposited with uniform epitaxial growth, resulting in a monocrystalline silicon layer with a controlled thickness.

As used herein, the term “silicon oxide layer” may be used to identify a thin film when depositing a silicon precursor on at least part of the substrate and reacting said deposited silicon with an oxygen reactant. Subsequently, when reacting the silicon layer with a halide reactant, the thin film may be identified as a “surface-modified silicon oxide layer”. It should be understood that the herein disclosed surface-modified silicon oxide layer comprises silicon oxide (SiO₂) and optionally silicon (Si). The ratio of silicon oxide and silicon in the surface-modified silicon oxide layer may depend on the nature and amount of the silicon precursor, oxygen reactant, and halide reactant.

As used herein, the term “silicon nitride layer” may be used to identify a thin film when depositing a silicon precursor on at least part of the substrate and reacting said deposited silicon with a nitrogen reactant. Subsequently, when reacting the silicon layer with a halide reactant, the thin film may be identified as a “surface-modified silicon nitride layer”. It should be understood that the herein disclosed surface-modified silicon nitride layer comprises silicon nitride (SiN) and optionally silicon (Si). The ratio of silicon nitride and silicon in the surface-modified silicon nitride layer may depend on the nature and amount of the silicon precursor, nitrogen reactant, and halide reactant.

As used herein, the term “epitaxial growth” refers to a type of crystalline growth or material deposition in which new layers are formed with one or more well-defined orientation with respect to a substrate. The deposited crystalline thin film may be also called an “epitaxial film” or “epitaxial layer”. For instance, an “epitaxial wafer” or “epi wafer” may be a semiconducting structure made by epitaxial growth wherein the grown layer may be the same material as the substrate (e.g. monocrystalline silicon) or it may be different. Typically, precursor deposition in a semiconductor manufacturing process involves reversible reactions under chemical equilibrium, wherein the growth rate depends on the proportion of each precursor source and/or reactant source, often expressed as the volumetric flow rate. In gas-phase reactions, such as chemical or physical vapor deposition, different side-reactions may compete with the silicon deposition reaction, resulting in surface defects and non-uniform deposition (e.g. edge effect). Commonly, to remove edge effects, additional steps such as etching or polishing and/or equipment such as a holder boat or ring boat are needed to control excess deposition. However, said additional steps and/or equipment provide several disadvantages for the manufacturing of semiconductors. For instance, non-uniform etching may adversely affect (electro-) chemical stability of the formed semiconductor. Moreover, non-selective etching or masking may lead to variations in material properties, feature depth, and impurities.

Advantageously, the present inventors have found that the combination of a silicon precursor and a halide reactant within the same and/or different pulse or deposition results in a balanced epitaxial growth and improved thin-film formation. Furthermore, compared to methods that remove edge effects in semiconductor manufacturing in the state of the art, the herein disclosed method offers a significant reduction in the number of reagents or precursors, and purification steps required for the formation of silicon layers with high uniformity. As used herein, the term “surface-modified silicon layer” may be used to identify such an improved silicon thin film with uniform thickness and smooth surface (i.e. low surface roughness) without the need for additional etching or polishing.

In some particular embodiments, the method as disclosed herein provides that the silicon precursor and halide reactant are simultaneously introduced in the reaction chamber. Hence, the silicon precursor pulse and halide reactant pulse may be combined to co-flow or simultaneously introduce the silicon precursor (gas) and the halide reactant (gas) in the reaction chamber. Without wishing to be bound by theory, it is found that the difference in reactivity between the silicon precursor and the halide reactant with respect to the surface of the substrate may allow for selective epitaxial growth and controlled material deposition.

In some particular embodiments, the method as disclosed herein provides that the silicon precursor may be introduced in the reaction chamber prior to the halide reactant. This notwithstanding, and in other embodiments, the halide reactant compound pulse may precede the silicon precursor pulse.

It shall be understood that any two steps and/or pulses can be separated by a purge. Thus, in some embodiments, the step of contacting the silicon precursor and the step of reacting the halide reactant are separated by a purge. In some embodiments, subsequent cycles are separated by a purge.

In some embodiments, the substrate may be made from semiconductor materials, including, for example, silicon, silicon germanium, silicon oxide, gallium arsenide, gallium nitride and silicon carbide. In some preferred embodiments, the substrate may be made from silicon oxide, silicon germanium, gallium arsenide, indium gallium arsenide, gallium nitride, and/or silicon nitride.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

It has been found that the ratio of the silicon precursor and the halide reactant may be varied to accelerate or deaccelerate epitaxial growth across the surface of the substrate, and more particularly at the edge of the surface of the substrate, resulting in a surface-modified silicon layer with improved thickness uniformity and smooth surface. In particular embodiments, the method as disclosed herein provides that the silicon precursor and halide reactant are introduced in the reaction chamber at a volumetric flow rate ratio of silicon precursor/halide reactant of at least 1.1 and at most 1000.0, or at least 1.1 and at most 900.0, or at least 1.1 and at most 800.0, or at least 1.1 and at most 700.0, or at least 1.1 and at most 600.0, or at least 1.1 and at most 500.0, or at least 1.1 and at most 400.0, or at least 1.1 and at most 300.0, or at least 1.1 and at most 200.0, or at least 1.1 and at most 100.0, or at least 1.5 and at most 100.0, or at least 2 and at most 100.0, or at least 2.5 and at most 100.0, or at least 3.0 and at most 100.0, or at least 3.5 and at most 100.0, or at least 4.0 and at most 100.0, or at least 4.5 and at most 100.0, or at least 5.0 and at most 100.0, or at least 5.0 and at most 90.0, or at least 5.0 and at most 80.0, or at least 5.0 and at most 70.0, or at least 5.0 and at most 60.0, or at least 5.0 and at most 50.0, or at least 5.0 and at most 40.0, or at least 5.0 and at most 30.0, or at least 5.0 and at most 20.0. An advantage of the herein disclosed volumetric flow rate ratio of silicon precursor/halide reactant is the flexibility to adjust the volumetric flow rate of halide reactant to the volumetric ratio of silane precursor depending on intrinsic reactivity towards the surface of the substrate and/or formation of polysilicon hydride intermediates.

In particular embodiments, the method as disclosed herein provides that the silicon precursor may be chosen from the group including at least one of least one of SiₙH₂ₙ₊₂, SiₙH₂ₙ, and Si(OR¹)₄; wherein n is an integer from 1 to 20 and m is an integer from 3 to 20; and wherein each R¹ is independently selected from the group consisting of C₁₋₈alkyl. In this disclosure n is an integer from 1 to 20, or from 1 to 15, preferably from 1 to 10, or from 1 to 8, more preferably from 1 to 6, most preferably from 1 to 4. In this disclosure m is an integer from 3 to 20, or from 3 to 12, preferably from 3 to 10, or from 3 to 8, more preferably from 3 to 6, most preferably from 3 to 5.

In particular embodiments, the method as disclosed herein provides that the silicon precursor may be chosen from the group consisting of silane (SiH₄), disilane (Si₂H₆), trisilane (Si₃H₈), tetrasilane (Si₄H₁₀), isotetrasilane, pentasilane (Si₅H₁₂), isopentasilane, neopentasilane, hexasilane (Si₆H₁₄), cyclotrisilane (Si₃H₆), cyclotetrasilane (Si₄H₈), cyclopentasilane (Si₅H₁₀), cyclohexasilane (Si₆H₁₂), tetramethyl orthosilicate (Si(OCH₃)₄), and tetraethyl orthosilicate (Si(OC₂H₅)₄). It may be appreciated that in principle any silicon compound consisting of one or more Si—H bond could be comprised in the silicon precursor. Higher order silanes, such as trisilane, are generally more thermally labile and may increase the growth rate of the silicon layer.

In general, the herein disclosed halide reactant can be considered to consist of at least one halogen functional group (—X, wherein X=F, Cl, Br, or I). In particular embodiments, the halide reactant may be selected from the group consisting of elemental halogen, and a halogen compound; and wherein the halogen compound comprises an element selected from the group consisting of H, B, Al, Si, P, O, N, and S, and one or more halogen.

In particular embodiments, the method as disclosed herein provides that the halide reactant may be chosen from the group consisting of fluorine (F₂), chlorine (Cl₂), bromine (Br₂), iodine (I₂), hydrogen fluoride (HF), hydrogen chloride (HCl), hydrogen bromide (HBr), hydrogen iodide (HI), phosphorus trifluoride (PF₃), phosphorus pentafluoride (PF₅), phosphorus trichloride (PCl₃), phosphorus pentachloride (PCl₅), thionyl chloride (SOCl₂), phosphorus tribromide (PBr₃), phosphorus pentabromide (PBr₅), thionyl bromide (SOBr₂), tetrafluorosilane (SiF₄), tetrachlorosilane (SiCl₄), tetrabromosilane (SiBr₄), trifluorosilane (SiHF₃), trichlorosilane (SiHCl₃), tribromosilane (SiHBr₃), difluorosilane (SiH₂F₂) dichlorosilane (SiH₂Cl₂), dibromosilane (SiH₂Br₂), fluorosilane (SiH₃F), chlorosilane (SiH₃Cl), bromosilane (SiH₃Br), hexafluorodisilane (Si₂F₆), hexachlorodisilane (Si₂Cl₆), hexabromodisilane (Si₂Br₆), octafluorotrisilane (Si₃F₈), octachlorotrisilane (Si₃Cl₈), octabromotrisilane (Si₃Br₈), boron trifluoride (BF₃), boron trichloride (BCl₃), boron tribromide (BBr₃), boron triiodide (BI₃), aluminium trifluoride (AlF₃), aluminium trichloride (AlCl₃), aluminium tribromide (AlBr₃), and aluminium triiodide (AlI₃). Advantageously, reacting the halide reactant with the deposited silicon material allows to obtain a surface-modified silicon layer with a uniform layer thickness and surface roughness by controlling the silicon growth rate. In some embodiments, the method as disclosed herein provides that the surface-modified silicon layer has an average surface roughness deviation of less than 10.0%, or less than 9.0%, or less than 8.0%, or less than 7.0%, or less than 6.0%, or less than 5.0%, preferably less than 3.0%.

In other embodiments, the method as disclosed herein provides that the surface-modified silicon layer has an average surface roughness deviation of less than 2.0%, or less than 1.0% or less than 0.5%. The skilled person understands how to measure the surface roughness deviation of a deposited surface-modified silicon layer. For instance, atomic force microscopy operated in tapping mode is a common analysis tool to determine the average surface roughness deviation. In some embodiments, the method as disclosed herein provides that the surface-modified silicon layer has an average thickness of 3 nm or less, or 2.5 nm or less, or 2 nm or less, or 1.5 nm or less, or 1 nm or less, or 0.5 nm or less, or 0.25 nm or less, or 0.10 nm or less.

In some embodiments, the method as disclosed herein provides that the formed surface-modified silicon layer has an average growth rate of at least 0.05 nm/min, preferably at least 0.10 nm/min, or at least 0.15 nm/min, or at least 0.20 nm/min, or at least 0.25 nm/min, or at least 0.30 nm/min, or at least 0.35 nm/min, or at least 0.40 nm/min, or at least 0.50 nm/min. The listed average growth rate values (per alternating pulses of precursor(s)/reactive gas(es), and purge (e.g., inert carrier) gas(es)) are advantageous for semiconductor manufacturing. In particular, the method as disclosed herein provides a controlled growth rate, which may be needed to avoid side-reactions and/or changes in morphology of the deposited silicon-containing film.

As used herein, the term “deposition” or “cyclic deposition” or “cyclic deposition process” or “cyclical deposition process” refers to a sequential introduction of silane precursors (and/or reactants) into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a deposition process as disclosed herein refers to an atomic layer deposition process. Typically, one deposition cycle may form a film or layer of about 0.10 nm. However, the experimental thickness may vary depending on the amount and type of cycles and available reaction sites on the substrate. In some preferred embodiments, the method as disclosed herein provides that the surface-modified silicon layer has an average thickness of 3 nm or less, or 2.5 nm or less, or 2 nm or less, or 1.5 nm or less, or 1 nm or less, or 0.5 nm or less, or 0.25 nm or less, or 0.10 nm or less. A layer of lower thickness may be desirable for many electronics applications, including work function and/or threshold voltage adjustment in transistors.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a (silicon) precursor may be introduced to a reaction chamber and may be chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a (halide, oxygen and/or nitrogen) reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present disclosure allows to deposit uniform surface-modified silicon layers with little or no surface defects.

As used herein, the term “deposition” refers to a sequential introduction of precursors (and/or reactants) into a reaction chamber to deposit a layer or thin-film over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a deposition process as disclosed herein refers to an atomic layer deposition process. Examples of a reaction chamber or process chamber include a cross-flow reactor, a showerhead reactor, or a hot-wall reactor.

The term “atomic layer deposition” (ALD) refers to a vapor deposition process in which material deposits, typically a plurality of consecutive material deposits, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Generally, for ALD processes, during each consecutive deposit, a (metal) precursor may be introduced to a reaction chamber and may be chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present invention allows to form surface-modified silicon layers in a single ALD process. Hence, allowing faster deposition with a larger error-tolerance compared to what is disclosed in the state of the art.

In some embodiments, the plurality of deposition cycles can comprise a plurality of master cycles. A master cycle can comprise a halide reactant pulse and one or more sub-cycles. A sub-cycle may comprise a silicon precursor pulse. A sub-cycle may comprise a silicon precursor pulse followed by an oxygen reactant pulse. A sub-cycle may comprise a silicon precursor pulse followed by a nitrogen reactant pulse. Thus, in some embodiments, the plurality of deposition cycles can be represented by formula i)

[(silicon precursor)×sub-cycle+halide reactant]×master cycle i)

Additionally, or alternatively, and in some embodiments, the plurality of deposition cycles can be represented by formula ii)

[(silicon precursor+oxygen reactant)×sub-cycle+halide reactant]×master cycle ii)

Additionally, or alternatively, and in some embodiments, the plurality of deposition cycles can be represented by formula iii)

[(silicon precursor+nitrogen reactant)×sub-cycle+halide reactant]×master cycle iii)

In which “silicon precursor” denotes a silicon precursor pulse, “oxygen reactant” denotes an oxygen reactant pulse, “nitrogen reactant” denotes a nitrogen reactant pulse, “x sub-cycle” denotes the number of sub-cycles per master cycle, “halide reactant” denotes a halide reactant pulse, “x master cycle” denotes the number of master cycles, and “+” denotes that one pulse occurs after the other. In such embodiments, a halide reactant is only introduced during the halide reactant pulse, such that edge defects are minimalized.

In some embodiments, the method comprises from at least 2 sub-cycles to at most 5 sub-cycles, or from at least 5 sub-cycles to at most 10 sub-cycles, or from at least 10 sub-cycles to at most 20 sub-cycles, or from at least 20 sub-cycles to at most 50 sub-cycles, or from at least 50 sub-cycles to at most 100 sub-cycles, or from at least 100 sub-cycles to at most 200 sub-cycles, or from at least 200 sub-cycles to at most 500 sub-cycles, or from at least 500 sub-cycles to at most 1000 sub-cycles, or from at least 1000 sub-cycles to at most 2000 sub-cycles.

In some embodiments, the silicon precursor pulse lasts from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the halide reactant pulse and/or oxygen reactant pulse and/or nitrogen reactant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

The method as disclosed herein may be performed at different temperatures and/or pressures. In some embodiments, the substrate may be heated to a temperature of at least 200° C. and at most 1000° C., or at least 200° C. and at most 800° C., or at least 200° C. and at most 750° C., or at least 200° C. and at most 700° C., or at least 300° C. and at most 750° C., or at least 300° C. and at most 700° C., or at least 300° C. and at most 650° C., preferably at least 350° C. and at most 650° C. The listed temperatures can decrease the time needed for material deposition, although lower or higher temperatures can be considered still. In some embodiments, the reaction chamber has a pressure of at least 0.1 Torr and at most 50.0 Torr, or at least 0.1 Torr and at most 40.0 Torr, or at least 0.1 Torr and at most 30.0 Torr, or at least 0.1 Torr and at most 20.0 Torr, or at least 0.5 Torr and at most 20.0 Torr, preferably at least 0.5 Torr and at most 10 Torr. The listed pressures can decrease the time needed for material deposition, although lower or higher pressures can be considered still.

The surface-modified silicon layer can be deposited in any suitable reactor. Thus, in some embodiments, the surface-modified silicon layer may be deposited in a cross-flow reactor. In some embodiments, the surface-modified silicon layer may be deposited in a showerhead reactor. In some embodiments, the surface-modified silicon layer may be deposited in a hot-wall reactor. Doing so can advantageously enhance uniformity and/or repeatability of surface-modified silicon layer deposition processes.

In some embodiments, the substrate may be subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the silicon precursor may be provided to the reaction chamber from a temperature-controlled precursor vessel. In some embodiments, the temperature-controlled precursor vessel may be configured for cooling the precursor. In some embodiments, the temperature-controlled precursor vessel may be configured for heating the precursor. In some embodiments, the temperature controlled precursor vessel may be maintained at a temperature of at least-50° C. to at most 20° C., or at a temperature of at least 20° C. to at most 250° C., or at a temperature of at least 100° C. to at most 200° C.

In some embodiments, the silicon precursor may be provided to the reaction chamber by means of a carrier gas. Exemplary carrier gasses include nitrogen (N₂) and a noble gas such as He, Ne, Ar, Xe, or Kr.

Suitable surface-modified silicon layers as disclosed herein may include doped or undoped silicon. Undoped silicon can be referred to as intrinsic silicon. Doped silicon can include an n-type dopant comprising pentavalent elements phosphorous (P), arsenic (As), and/or antimony (Sb). Additionally or alternatively, doped silicon can include a p-type dopant comprising trivalent elements boron (B), aluminum (Al), or indium (In). The term “dopant” as used herein refers to a compound, chemical agent, or impurity added to a semiconductor to improve electric conductivity. To introduce the dopant into the surface-modified silicon layer as disclosed herein, a variety of vapor deposition techniques may be used which in general comprise at least two steps. First, the dopant may be deposited on the surface of the uniform silicon film and subsequently the deposited dopant layer may be incorporated or driven into the bulk of the surface-modified silicon layer.

In particular embodiments, the method as disclosed herein further comprises a step c) of doping the formed surface-modified silicon layer with a dopant, wherein the dopant comprises an element from the group including at least one of P, As, Sb, B, Al, and In. In some preferred embodiments, the dopant may be chosen from the group consisting of PH₃, PF₅, PCl₅, PBr₅, AsF₅, AsCl₅, AsBr₅, AsH₃, SbF₃, SbCl₃, SbBr₃, BF₃, BCl₃, BBr₃, B₂H₆, AlF₃, AlCl₃, AlBr₃, InF₃, InCl₃, and InBr₃. The listed dopants are advantageous for precursor deposition in a semiconductor manufacturing process with improved surface characteristics and less defects (e.g. edge effect).

In another aspect of the invention, the present disclosure relates to a layered structure comprising:
a substrate, and
one or more surface-modified silicon layers deposited on at least part of the substrate;
characterized in that the one or more surface-modified silicon layers have an average surface roughness deviation of less than 10.0%, or less than 9.0%, or less than 8.0%, or less than 7.0%, or less than 6.0%, or less than 5.0%, preferably less than 3.0%. In some embodiments, a semiconductor comprises the layered structure as disclosed herein. In particular embodiments, the layered structure as disclosed herein provides that the one or more surface-modified silicon layers has an average thickness of 3 nm or less, or 2 nm or less, or 1 nm or less, or 0.5 nm or less.

In particular embodiments, the layered structure as disclosed herein provides that the one or more surface-modified silicon layers are obtained according to the method as disclosed herein. Advantageously, the herein disclosed one or more surface-modified silicon layers are characterized by a lower amount of deposition defects, a controlled layer thickness, and a smooth surface, when compared to silicon layers reported in the state of the art, leading to improved electrical properties of the resulting semiconductor.

In some embodiments, the layered structure further comprises a dopant, and wherein the dopant comprises an element from the group including at least one of P, As, Sb, B, Al, and In. In particular, the dopant may be comprised in at least one of the one or more surface-modified silicon layers, resulting in a layered structure with improved conductive properties.

In another aspect of the invention, the present disclosure relates to the use of a halide reactant for reducing the With-In Wafer Non-Uniformity (WIWNU) of surface-modified silicon layers. As disclosed herein, the halide reactant can accelerate and/or deaccelerate the growth rate of a silicon layer at the edge of the surface when depositing silicon on said surface. Moreover, the silicon growth rate can be independently adjusted by controlling the silicon precursor pulse (growth pulse) and halide reactant pulse (etching pulse). In particular embodiments, the herein disclosed use of the halide reactant provides that the surface-modified silicon layers have an average surface roughness deviation of less than 10.0%, or less than 9.0%, or less than 8.0%, or less than 7.0%, or less than 6.0%, or less than 5.0%, preferably less than 3.0%. In particular embodiments, the halide reactant may be chosen from the group consisting of fluorine (F₂), chlorine (Cl₂), bromine (Br₂), iodine (I₂), hydrogen fluoride (HF), hydrogen chloride (HCl), hydrogen bromide (HBr), hydrogen iodide (HI), phosphorus trifluoride (PF₃), phosphorus pentafluoride (PF₅), phosphorus trichloride (PCl₃), phosphorus pentachloride (PCl₅), thionyl chloride (SOCl₂), phosphorus tribromide (PBr₃), phosphorus pentabromide (PBr₅), thionyl bromide (SOBr₂), tetrafluorosilane (SiF₄), tetrachlorosilane (SiCl₄), tetrabromosilane (SiBr₄), trifluorosilane (SiHF₃), trichlorosilane (SiHCl₃), tribromosilane (SiHBr₃), difluorosilane (SiH₂F₂) dichlorosilane (SiH₂Cl₂), dibromosilane (SiH₂Br₂), fluorosilane (SiH₃F), chlorosilane (SiH₃Cl), bromosilane (SiH₃Br), hexafluorodisilane (Si₂F₆), hexachlorodisilane (Si₂Cl₆), hexabromodisilane (Si₂Br₆), octafluorotrisilane (Si₃F₈), octachlorotrisilane (Si₃Cl₈), octabromotrisilane (Si₃Br₈), boron trifluoride (BF₃), boron trichloride (BCl₃), boron tribromide (BBr₃), boron triiodide (BI₃), aluminium trifluoride (AlF₃), aluminium trichloride (AlCl₃), aluminium tribromide (AlBr₃), and aluminium triiodide (AlI₃).

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### EXAMPLES

Examples of an implementation of the technology according to the present disclosure is given hereinbelow. The provision of examples is meant to aid the reader in understanding the technological concepts more easily, but it is not meant to identify the most important or essential features thereof, nor is it meant to limit the scope of the present disclosure.

### Example 1—Uniform Surface-Modified Silicon Layer

To demonstrate the improved reduction in With-In Wafer Non-Uniformity (WIWNU) of the surface-modified silicon layers obtained by the method as disclosed herein, a layered structure was formed by exposing a silicon substrate to:
a silicon precursor pulse (Si₃H₈) to obtain Comparative Example 1;
a co-flow of a silicon precursor pulse (Si₃H₈) and a halide reactant pulse (BCl₃) to obtain Example 1;
using a chemical vapor deposition (CVD) process.

The following parameters were used for the CVD process of Comparative Example 1:
Temperature of the substrate: 400° C.
Pressure in the reaction chamber: 0.2 Torr
Trisilane (Si₃H₈) exposure: 3000 s

The following parameters were used for the CVD process of Example 1:
Temperature of the substrate: 400° C.
Pressure in the reaction chamber: 0.2 Torr
Trisilane (Si₃H₈) and boron trichloride (BCl₃) exposure: 3000 s

As shown in FIG. 5 for Example 1, the addition of the halide reactant reduced the WIWNU by approximately 23-fold. Especially at the edge of the silicon wafer, an increase of silicon deposit could be seen for Comparative Example 1.

### Example 2

The following parameters were used for the CVD process of Comparative Example 2:
Temperature of the substrate: 400° C.
Pressure in the reaction chamber: 0.2 Torr
Trisilane (Si₃H₈) pulse: 300 s
Purge time after Trisilane (Si₃H₈) pulse: 5 s
Amount of repetitions of the pulsing sequence: 10

The following parameters were used for the CVD process of Example 2:
Temperature of the substrate: 400° C.
Pressure in the reaction chamber: 0.2 Torr
Trisilane (Si₃H₈) pulse: 300 s
Purge time after Trisilane (Si₃H₈) pulse: 5 s
Boron trichloride (BCl₃) pulse: 5 s
Purge time after Boron trichloride (BCl₃) pulse: 5 s
Amount of repetitions of the pulsing sequence: 10

1. A method for precursor deposition in a semiconductor manufacturing process, the method comprising the steps of:
a) providing a substrate to a reaction chamber; and
b) executing one or more cycles, a cycle comprising
i. contacting a silicon precursor with at least a part of said substrate by introducing said silicon precursor in the reaction chamber; and
ii. contacting a halide reactant with at least a part of said substrate by introducing said halide reactant in said reaction chamber,
thereby forming a surface-modified silicon layer on at least part of said substrate.

2. The method according to claim 1, wherein the cycle of step b) further comprises
contacting an oxygen reactant with at least a part of said substrate by introducing said oxygen reactant in said reaction chamber,
thereby forming a surface-modified silicon oxide layer on at least part of said substrate.

3. The method according to claim 1, wherein the cycle of step b) further comprises
contacting a nitrogen reactant with at least a part of said substrate by introducing said nitrogen reactant in said reaction chamber thereby forming a surface-modified silicon nitride layer on at least part of said substrate.

4. The method according to claim 1, wherein said silicon precursor and said halide reactant are introduced in said reaction chamber at a volumetric flow rate ratio of silicon precursor/halide reactant of at least 1.1 to at most 100.0.

5. The method according to claim 1, wherein said silicon precursor is chosen from the group including at least one of SinH2n+2, SinH2n, and Si(OR1)4; wherein n is an integer from 1 to 20 and m is an integer from 3 to 20; and wherein each R1 is independently selected from the group consisting of C1-8alkyl.

6. The method according to claim 1, wherein the silicon precursor is chosen from the group consisting of silane (SiH4), disilane (Si2H6), trisilane (Si3H8), tetrasilane (Si4H10), isotetrasilane, pentasilane (Si5H12), isopentasilane, neopentasilane, hexasilane (Si6H14), cyclotrisilane (Si3H6), cyclotetrasilane (Si4H8), cyclopentasilane (Si5H10), cyclohexasilane (Si6H12), tetramethyl orthosilicate (Si(OCH3)4), and tetraethyl orthosilicate (Si(OC2H5)4).

7. The method according to claim 1, wherein said halide reactant is selected from the group consisting of elemental halogen, and a halogen compound; and wherein the halogen compound comprises an element selected from the group consisting of H, B, Al, Si, P, O, N, and S, and one or more halogen.

8. The method according to claim 1, wherein said halide reactant is chosen from the group consisting of fluorine (F2), chlorine (Cl2), bromine (Br2), iodine (I2), hydrogen fluoride (HF), hydrogen chloride (HCl), hydrogen bromide (HBr), hydrogen iodide (HI), phosphorus trifluoride (PF3), phosphorus pentafluoride (PF5), phosphorus trichloride (PCl3), phosphorus pentachloride (PCl5), thionyl chloride (SOCl2), phosphorus tribromide (PBr3), phosphorus pentabromide (PBr5), thionyl bromide (SOBr2), tetrafluorosilane (SiF4), tetrachlorosilane (SiCl4), tetrabromosilane (SiBr4), trifluorosilane (SiHF3), trichlorosilane (SiHCl3), tribromosilane (SiHBr3), difluorosilane (SiH2F2) dichlorosilane (SiH2Cl2), dibromosilane (SiH2Br2), fluorosilane (SiH3F), chlorosilane (SiH3Cl), bromosilane (SiH3Br), hexafluorodisilane (Si2F6), hexachlorodisilane (Si2Cl6), hexabromodisilane (Si2Br6), octafluorotrisilane (Si3F8), octachlorotrisilane (Si3Cl8), octabromotrisilane (Si3Br8), boron trifluoride (BF3), boron trichloride (BCl3), boron tribromide (BBr3), boron triiodide (BI3), aluminium trifluoride (AlF3), aluminium trichloride (AlCl3), aluminium tribromide (AlBr3), and aluminium triiodide (AlI3).

9. The method according to claim 1, wherein the formed surface-modified silicon layer has an average growth rate of at least 0.10 nm/min.

10. The method according to claim 1, wherein the substrate is heated to a temperature of at least 200° C. and at most 1000° C.

11. The method according to claim 1, wherein the reaction chamber has a pressure of at least 0.1 Torr and at most 50.0 Torr.

12. The method according to claim 1, wherein the surface-modified silicon layer has an average surface roughness deviation of less than 3.0%.

13. The method according to claim 1, wherein the surface-modified silicon layer has an average thickness of 1 nm or less.

14. The method according to claim 1, further comprising a step c) of doping the formed surface-modified silicon layer with a dopant, wherein the dopant comprises an element from the group including at least one of P, As, Sb, B, Al, and In.

15. A system comprising:
one or more reaction chamber constructed and arranged to hold a substrate;
a silicon precursor vessel constructed and arranged to contain and evaporate a silicon precursor;
a halide reactant vessel constructed and arranged to contain and evaporate a halide reactant;
an exhaust source; and
a controller, wherein the controller is configured to control the flow of said silicon precursor and said halide reactant into said reaction chamber, thereby forming a surface-modified silicon layer on said substrate.

16. A layered structure comprising:
a substrate, and
one or more surface-modified silicon layers deposited on at least a part of the substrate,
wherein the one or more surface-modified silicon layers have an average surface roughness deviation of less than 10.0%.

17. The layered structure according to claim 16, wherein the one or more surface-modified silicon layers have an average surface roughness deviation of less than 3.0%.

18. The layered structure according to claim 16, wherein each of the one or more surface-modified silicon layers has an average thickness of 1 nm or less.

19. The layered structure according to claim 16, wherein the layered structure further comprises a dopant, and wherein the dopant comprises an element from the group including at least one of P, As, Sb, B, Al, and In.

20. Use of a halide reactant for reducing the Within Wafer Non-Uniformity (WIWNU) of surface-modified silicon-containing layers.
